(19) United States
(12) Patent Application Publication
(10) Pub. No.: US 2020/0252049 A1
(43) Pub. Date: Aug. 6, 2020

(54) RESONATOR DEVICE, RESONATOR MODULE, ELECTRONIC APPARATUS, AND VEHICLE

(71) Applicant: SEIKO EPSON CORPORATION, Tokyo (JP)

(72) Inventors: Masahiro FUJII, SHIOJIRI-SHI (JP); Ryuichi KUROSAWA, HARA-MURA (JP)

(21) Appl. No.: 16/776,076

(22) Filed: Jan. 29, 2020

(30) Foreign Application Priority Data
Jan. 31, 2019 (JP) 2019-015323

(51) Int. Cl. H03H 9/19; C30B 29/06; H01L 23/31; H01L 21/8258; H03B 5/30; H03H 3/04; H03H 9/05; H01L 21/306

(52) U.S. Cl. CPC H03H 9/19; C30B 29/06; H01L 23/3121; H01L 21/30604; H03B 5/30; H03H 3/04; H03H 9/0595; H01L 21/8258

(57) ABSTRACT

A resonator device includes a base substrate including a principal surface, a side surface, and an inclined surface that couples the principal surface to the side surface and that is inclined with respect to the principal surface and the side surface, a resonator element arranged on the principal surface of the base substrate, and a lid that is bonded to the principal surface of the base substrate and accommodates the resonator element between the lid and the base substrate. A bonding area in which the base substrate and the lid are bonded is positioned inside an outer edge of the principal surface.

The present application is based on, and claims priority from JP Application Serial Number 2019-015323, filed Jan. 31, 2019, the disclosure of which is hereby incorporated by reference herein in its entirety.

### BACKGROUND

### 1. Technical Field

The present disclosure relates to a resonator device, a manufacturing method for a resonator device, a resonator module, an electronic apparatus, and a vehicle.

### 2. Related Art

A manufacturing method for a quartz crystal resonator is disclosed in JP-A-2014-175853. The manufacturing method includes a step of preparing a base substrate including a plurality of dicing areas, a step of mounting a quartz crystal resonator element in each dicing area, a step of bonding a lid substrate including the same plurality of dicing areas as the base substrate to the base substrate and forming a plurality of resonators at once, and a step of dicing each dicing area. Accordingly, a quartz crystal resonator including a base, a quartz crystal resonator element mounted on the base, and a lid bonded to the base to accommodate the quartz crystal resonator element is obtained. In addition, in the dicing step of JP-A-2014-175853, first, a V-shaped groove that reaches the base substrate from the lid substrate is formed along boundaries of the dicing areas. Next, the dicing is performed by causing fracture from the groove by applying stress.

However, in JP-A-2014-175853, the side surfaces of the base and the lid are planar, and the outer edges of the base and the lid are bonded to each other. Thus, for example, when external stress is applied at the time of falling down or handling of the quartz crystal resonator, stress is likely to be applied to a bonding part, and the strength of the bonding part may be decreased.

### SUMMARY

A resonator device according to an application example includes abase substrate including a principal surface, a side surface, and an inclined surface that couples the principal surface to the side surface and that is inclined with respect to the principal surface and the side surface, a resonator element arranged on the principal surface side of the base substrate, and a lid that is bonded to the principal surface of the base substrate to accommodate the resonator element between the lid and the base substrate. A bonding area in which the base substrate and the lid are bonded is positioned inside an outer edge of the principal surface.

A manufacturing method for a resonator device according to another application example includes preparing a base wafer that includes a plurality of dicing areas and in which a groove is formed along a boundary between the adjacent dicing areas on a first surface side which is one principal surface, and arranging a resonator element on the first surface side in each dicing area, preparing a lid wafer that includes the plurality of dicing areas and in which a first recess accommodating the resonator element and a second recess which is along the boundary between the adjacent dicing areas and which has a depth greater than a depth of the first recess and an opening width greater than an opening width of the groove are formed on a second surface side which is a principal surface on the base wafer side, and obtaining a device wafer that is a stack of the base wafer and the lid wafer by bonding the first surface to the second surface, and dicing each dicing area by fracturing the base wafer from a tip end of the groove by applying stress to the device wafer.

A resonator module according to another application example includes the resonator device.

An electronic apparatus according to another application example includes the resonator device.

A vehicle according to another application example includes the resonator device.

### BRIEF DESCRIPTION OF THE DRAWINGS

FIG. 1 is a perspective view illustrating a resonator device according to a first embodiment.

FIG. 2 is a II-II sectional view of FIG. 1.

FIG. 3 is a III-III sectional view of FIG. 1.

FIG. 4 is a plan view of the resonator device illustrated in FIG. 1.

FIG. 5 is a sectional view illustrating a bonding part between a base substrate and a lid.

FIG. 6 is a plan view of a resonator element.

FIG. 7 is a see-through view of the resonator element seen from above.

FIG. 8 is a diagram illustrating a manufacturing step of the resonator device.

FIG. 9 is a sectional view illustrating the manufacturing step of the resonator device.

FIG. 10 is a sectional view illustrating the manufacturing step of the resonator device.

FIG. 11 is a sectional view illustrating the manufacturing step of the resonator device.

FIG. 12 is a sectional view illustrating the manufacturing step of the resonator device.

FIG. 13 is a sectional view illustrating the manufacturing step of the resonator device.

FIG. 14 is a sectional view illustrating the manufacturing step of the resonator device.

FIG. 15 is a sectional view illustrating the manufacturing step of the resonator device.

FIG. 16 is a sectional view illustrating the manufacturing step of the resonator device.

FIG. 17 is a sectional view illustrating the manufacturing step of the resonator device.

FIG. 18 is a sectional view illustrating the manufacturing step of the resonator device.

FIG. 19 is a sectional view illustrating the manufacturing step of the resonator device.

FIG. 20 is a sectional view illustrating a resonator device according to a second embodiment.

FIG. 21 is a sectional view illustrating a resonator module according to a third embodiment.

FIG. 22 is a perspective view illustrating an electronic apparatus according to a fourth embodiment.

FIG. 23 is a perspective view illustrating an electronic apparatus according to a fifth embodiment.

FIG. 24 is a perspective view illustrating an electronic apparatus according to a sixth embodiment.

FIG. 25 is a perspective view illustrating a vehicle according to a seventh embodiment.

### DESCRIPTION OF EXEMPLARY EMBODIMENTS

Hereinafter, a resonator device, a manufacturing method for a resonator device, a resonator module, an electronic apparatus, and a vehicle of the present application example will be described in detail based on embodiments illustrated in the appended drawings.

### First Embodiment

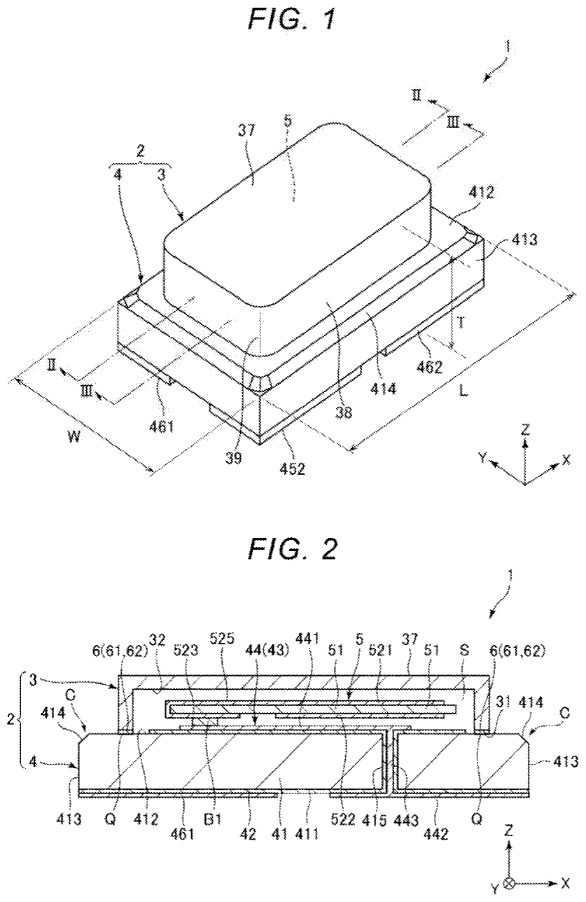

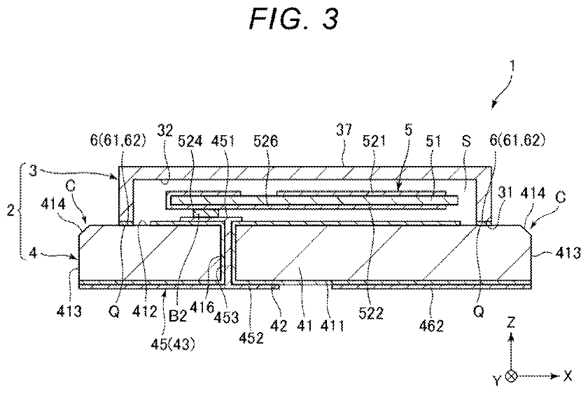

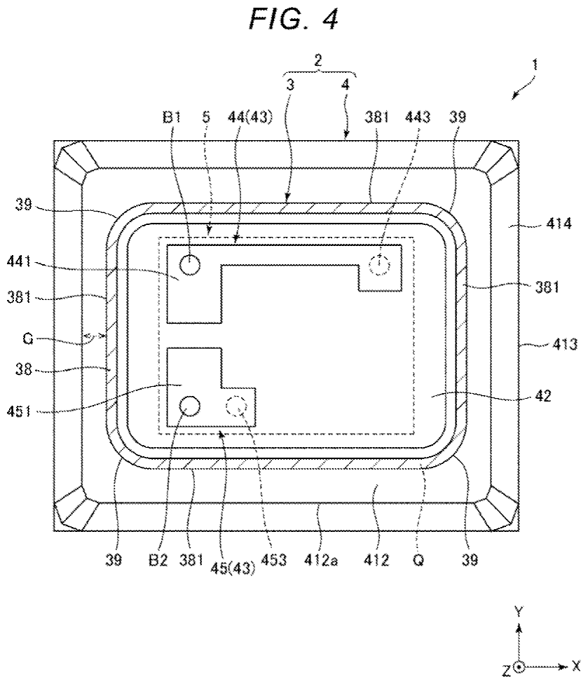

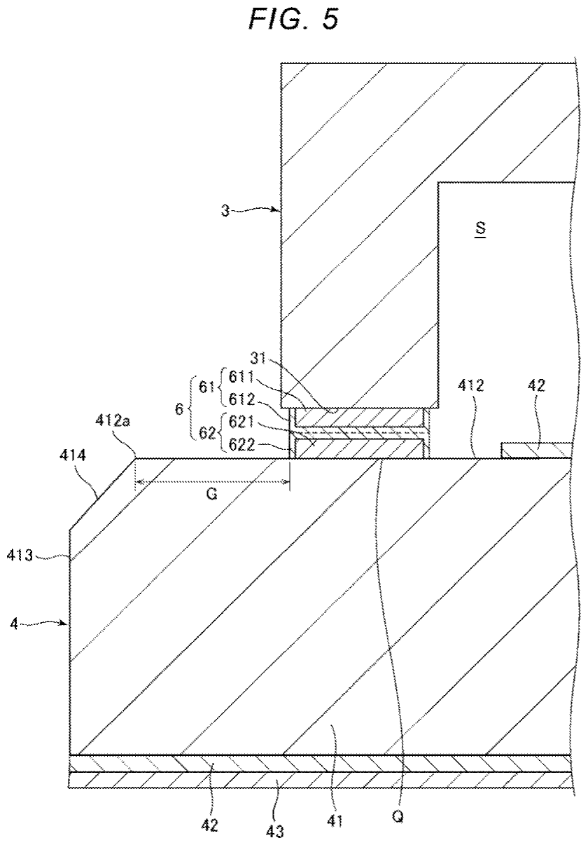

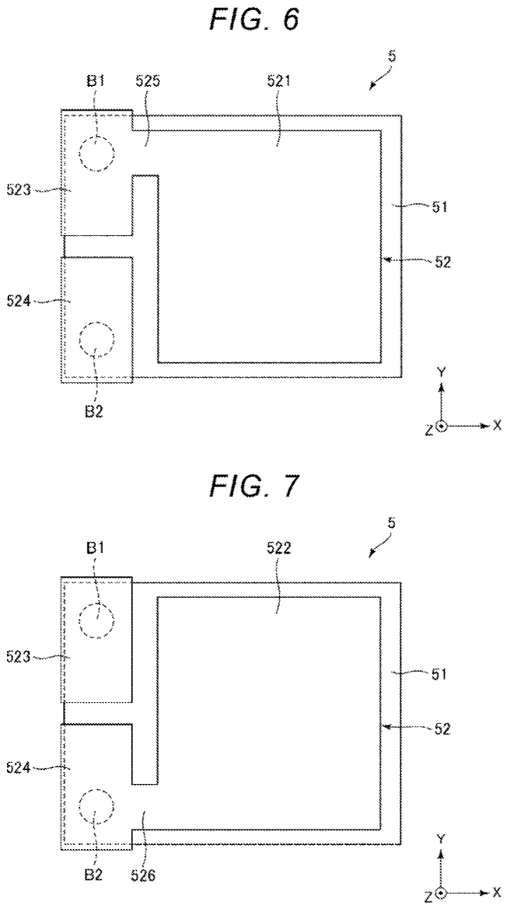

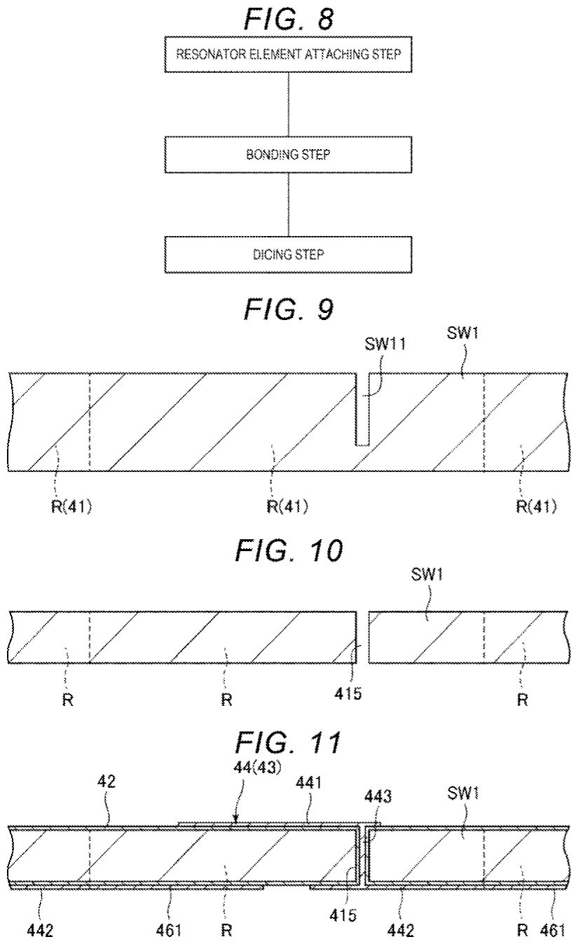

FIG. 1 is a perspective view illustrating a resonator device according to a first embodiment. FIG. 2 is a II-II sectional view of FIG. 1. FIG. 3 is a III-III sectional view of FIG. 1. FIG. 4 is a plan view of the resonator device illustrated in FIG. 1. FIG. 5 is a sectional view illustrating a bonding part between a base substrate and a lid. FIG. 6 is a plan view of a resonator element. FIG. 7 is a see-through view of the resonator element seen from above. FIG. 8 is a diagram illustrating a manufacturing step of the resonator device. FIG. 9 to FIG. 19 are sectional views illustrating the manufacturing step of the resonator device. For convenience of description, three axes that are orthogonal to each other are illustrated as an X axis, a Y axis, and a Z axis in each drawing. In FIG. 2 and FIG. 4, the positive side of the Z axis denotes the “top”, and the negative side of the Z axis denotes the “bottom”. A plan view from the thickness direction of the base substrate will be simply referred to as a “plan view”.

For example, it is assumed that a resonator device 1 illustrated in FIG. 1 is a small size resonator device of which a length L×width W×height T is approximately 1.2 mm×1.0 mm×0.5 mm. However, the size of the resonator device 1 is not particularly limited.

As illustrated in FIG. 1, the resonator device 1 includes a resonator element 5 and a package 2 accommodating the resonator element 5. As illustrated in FIG. 2 and FIG. 3, the package 2 includes a lid 3 of a box shape including a recess 32 accommodating the resonator element 5, and a base 4 of a plate shape that covers the opening of the recess 32 and that is bonded to the lid 3. By covering the opening of the recess 32 with the base 4, an accommodation space S in which the resonator element 5 is accommodated is formed. The accommodation space S is airtight and is in a depressurized state or may be in a state closer to a vacuum. Accordingly, viscous resistance is decreased, and the resonator element 5 can be stably driven. The atmosphere of the accommodation space S is not particularly limited and may be, for example, an atmosphere in which inert gas such as nitrogen or Ar is sealed, or may be in an atmospheric state or a pressurized state other than the depressurized state.

The base 4 includes a base substrate 41 of a plate shape, an insulating film 42 arranged on the surface of the base substrate 41, and an electrode 43 arranged on the insulating film 42.

The base substrate 41 has a plan view shape of a rectangular plate and includes a lower surface 411 and an upper surface 412 that are in a front-rear relationship to each other, a side surface 413, and an inclined surface 414 that is positioned between the upper surface 412 and the side surface 413 and that couples the upper surface 412 to the side surface 413. The inclined surface 414 has a frame shape surrounding the whole periphery of the upper surface 412. The inner edge of the inclined surface 414 is coupled to the outer edge of the upper surface 412, and the outer edge of the inclined surface 414 is coupled to the upper end of the side surface 413. The side surface 413 is configured as a planar surface that is perpendicular to the upper surface 412. The inclined surface 414 is configured as a planar surface that is inclined with respect to the upper surface 412 and the side surface 413. By disposing the inclined surface 414, a corner C that is formed in a coupling portion between the upper surface 412 and the side surface 413 is cut. Thus, concentration of stress on the corner C is reduced, and the occurrence of a chip or a crack starting from the corner C can be effectively reduced.

In the present embodiment, the inclined surface 414 is formed to surround the whole periphery of the upper surface 412. However, the present embodiment is not for limitation purposes. The inclined surface 414 may be formed to surround a part of the upper surface 412. The inclined surface 414 is configured as a planar surface. However, the inclined surface 414 is not for limitation purposes and may be configured as a curved surface. Furthermore, as a modification example, it may be configured that the base substrate 41 is positioned between the lower surface 411 and the side surface 413 and includes an inclined surface coupling the lower surface 411 to the side surface 413.

As will be described in the manufacturing method described later, the side surface 413 is a fractured surface that is formed by developing a crack by stress. The inclined surface 414 is an etched surface formed by wet etching. By forming the side surface 413 as a fractured surface, the side surface 413 is obtained as a smoother surface. Thus, a chip or a crack is more unlikely to occur in the base substrate 41. In addition, by forming the inclined surface 414 as an etched surface, the inclined surface 414 can be more easily formed.

In addition, the base substrate 41 includes two through holes 415 and 416 that pass through the upper surface 412 and the lower surface 411.

The base substrate 41 is a semiconductor substrate. The semiconductor substrate is not particularly limited. For example, a silicon substrate, a germanium substrate, or a compound semiconductor substrate of GaP, GaAs, InP, or the like can be used. By using the semiconductor substrate as the base substrate 41, the base 4 can be formed using a semiconductor process. Thus, the size of the resonator device 1 can be reduced. In addition, as will be described later in other embodiments, a semiconductor circuit can be formed in the base 4, and the base 4 can be effectively used. Particularly, in the present embodiment, a single crystal silicon substrate of which the upper surface 412 is a (100) crystal surface is used as the base substrate 41. Accordingly, the base substrate 41 is inexpensive and is easily obtained. The base substrate 41 is not limited to the semiconductor substrate. For example, a ceramic substrate or a glass substrate can be used.

When the single crystal silicon substrate of which the upper surface 412 is the (100) crystal surface is used as the base substrate 41, a (111) crystal surface or a (101) crystal surface is exposed by performing wet etching on the base substrate 41. Thus, the inclined surface 414 can be easily formed using the crystal surface. That is, by forming the upper surface 412 as the (100) crystal surface and forming the inclined surface 414 as the (111) crystal surface or the (101) crystal surface, the base substrate 41 including the inclined surface 414 can be more simply formed. The inclination angle of the inclined surface 414 with respect to the upper surface 412 is not particularly limited. For example, the inclination angle is approximately greater than or equal to 30° and less than or equal to 60°.

The insulating film 42 is arranged on the surface of the base substrate 41. However, the insulating film 42 is not formed in a bonding area Q between the base substrate 41 and the lid 3 on the upper surface 412 of the base substrate 41. That is, in the bonding area Q, silicon constituting the upper surface 412 is exposed from the insulating film 42. The insulating film 42 is not particularly limited. In the present embodiment, a silicon oxide film (SiO₂ film) is used. A forming method for the insulating film 42 is not particularly limited. For example, the insulating film 42 may be formed by subjecting the surface of the base substrate 41 to thermal oxidation, or may be formed by plasma CVD using tetraethoxysilane (TEOS).

The electrode 43 is arranged on the insulating film 42. The electrode 43 includes a first interconnect 44 and a second interconnect 45 that are insulated by the insulating film 42. The first interconnect 44 includes an internal terminal 441 positioned on the upper surface 412 side, that is, inside the accommodation space S, an external terminal 442 positioned on the lower surface 411 side, that is, outside the accommodation space S, and a through electrode 443 that is formed in the through hole 415 and that electrically couples the internal terminal 441 to the external terminal 442. Similarly, the second interconnect 45 includes an internal terminal 451 positioned on the upper surface 412 side, an external terminal 452 positioned on the lower surface 411 side, and a through electrode 453 that is formed in the through hole 416 and that electrically couples the internal terminal 451 to the external terminal 452. In addition, the electrode 43 includes two dummy electrodes 461 and 462 arranged on the lower surface 411 side.

The lid 3 has a box shape and includes the bottomed recess 32 that is open on a lower surface 31. As illustrated in FIG. 4, the plan view shape of the lid 3 is a rectangle almost similar to the upper surface 412 of the base substrate 41, and is formed to be slightly smaller than the upper surface 412. That is, in plan view, the outer edge of the lid 3 does not overlap with an outer edge 412a of the upper surface 412 and is positioned inside the outer edge 412a. The lid 3 includes a side surface 38 that includes four planar surfaces 381. Each corner 39 among the four planar surfaces 381 is rounded. That is, each corner 39 is configured as a curved convex surface having an arc shape. Accordingly, concentration of stress on the corner 39 is reduced, and the occurrence of a crack or the like starting from the corner 39 can be effectively reduced. The shape of the lid 3 is not particularly limited. Each corner 39 may not be rounded. Furthermore, a corner between the side surface 38 and the upper surface 37 may be rounded.

The lid 3 is a semiconductor substrate. The semiconductor substrate is not particularly limited. For example, a silicon substrate, a germanium substrate, or a compound semiconductor substrate of GaP, GaAs, InP, or the like can be used. By using the semiconductor substrate as the lid 3, the lid 3 can be formed using a semiconductor process. Thus, the size of the resonator device 1 can be reduced. Particularly, in the present embodiment, a single crystal silicon substrate in which the lower surface 31 is the (100) crystal surface is used as the lid 3. Accordingly, the lid 3 is inexpensive and is easily obtained. In addition, the materials of the base substrate 41 and the lid 3 can be matched, and a difference in coefficient of thermal expansion between the materials can be substantially equal to zero. Thus, the occurrence of thermal stress caused by thermal expansion is reduced, and the resonator device 1 has excellent resonance characteristics.

The lid 3 is not limited to the semiconductor substrate. For example, a ceramic substrate or a glass substrate can be used. A type of substrate different from the base substrate 41 may be used as the lid 3. Particularly, when the glass substrate having light-transmitting characteristics is used as the lid 3, a part of an excitation electrode 521 can be removed by irradiating the resonator element 5 with a laser through the lid 3 after the manufacturing of the resonator device 1, and the frequency of the resonator element 5 can be adjusted.

The lid 3 is directly bonded to the upper surface 412 of the base substrate 41 through a bonding member 6 on the lower surface 31. In the present embodiment, the lid 3 and the base substrate 41 are bonded using diffusion bonding that uses diffusion between metals among types of direct bonding. Specifically, as illustrated in FIG. 5, a metal film 61 is disposed on the lower surface 31 of the lid 3, and a metal film 62 is disposed on the upper surface 412 of the base substrate 41. The bonding member 6 is formed by diffusion-bonding the lower surface of the metal film 61 to the upper surface of the metal film 62. The lid 3 and the base substrate 41 are bonded through the bonding member 6.

In the present embodiment, diffusion bonding is applied using the bonding member 6. Alternatively, the base substrate 41 and the lid 3 may be directly bonded without the bonding member 6. In this case, the single crystal silicon substrate can be applied as the base substrate 41, and the single crystal silicon substrate can be applied as the lid 3. As method of direct bonding without using the bonding member 6, for example, the surface of the bonding part between the base substrate 41 and the lid 3 is activated by irradiating the bonding part with inert gas such as Ar, and the activated parts are bonded to each other.

For example, the metal film 61 is configured by forming a plated layer 612 that is a stack of nickel (Ni)/palladium (Pd)/gold (Au) on a base portion 611 formed of copper (Cu). Similarly, the metal film 62 is configured by forming a plated layer 622 that is a stack of Ni/Pd/Au on a base portion 621 formed of Cu. Alternatively, the metal films 61 and 62 may be configured to include a ground layer that is a thin film of chrome or titanium, and a thin film of gold formed above the ground layer by sputtering. The layers of gold on the surfaces of the metal films 61 and 62 are diffusion-bonded. According to the diffusion bonding, the lid 3 and the base substrate 41 can be bonded at room temperature (a temperature lower than the melting points of the metal films 61 and 62). Thus, internal stress is unlikely to remain in the package 2, and thermal damage to the resonator element 5 is reduced.

The bonding area Q between the base substrate 41 and the lid 3 is positioned inside the outer edge 412a of the upper surface 412 in plan view. That is, a gap G is formed between the bonding area Q and the outer edge 412a. By arranging the bonding area Q at a position away from the outer edge 412a without an overlap between the bonding area Q and the outer edge 412a, external stress is unlikely to be applied to the bonding area Q. As a specific example, for example, when the resonator device 1 hits the ground by falling down, the bonding area Q does not directly come into contact with the ground. Thus, the bonding area Q does not directly receive impact caused by falling down. Accordingly, excessive stress is unlikely to be applied to the bonding area Q, and a decrease in strength or breakage of the bonding area Q can be effectively reduced.

The gap G is not particularly limited. For example, as described above, when the size of the resonator device 1 is approximately length L×width W=1.2 mm×1.0 mm, the gap G can be approximately greater than or equal to 0.01 mm and less than or equal to 0.05 mm. In the present embodiment, the whole area of the bonding area Q is positioned inside the outer edge 412a. However, the present embodiment is not for limitation purposes. A part of the bonding area Q may overlap with the outer edge 412a. In this case, the area in overlap with the outer edge 412a may be less than or equal to 30%, more desirably less than or equal to 20%, and further desirably less than or equal to 10% of the whole area.

As illustrated in FIG. 6 and FIG. 7, the resonator element 5 includes a resonator substrate 51 and an electrode 52 arranged on the surface of the resonator substrate 51. The resonator substrate 51 has a thickness shear resonation mode and is formed of an AT cut quartz crystal substrate in the present embodiment. The AT cut quartz crystal substrate has three-dimensional frequency-temperature characteristics and is used as the resonator element 5 having excellent temperature characteristics.

The electrode 52 includes the excitation electrode 521 arranged on the upper surface of the resonator substrate 51 and an excitation electrode 522 arranged on the lower surface of the resonator substrate 51 in opposition to the excitation electrode 521 through the resonator substrate 51. In addition, the electrode 52 includes a pair of terminals 523 and 524 arranged on the lower surface of the resonator substrate 51, an interconnect 525 electrically coupling the terminal 523 to the excitation electrode 521, and an interconnect 526 electrically coupling the terminal 524 to the excitation electrode 522.

The configuration of the resonator element 5 is not limited to the above configuration. For example, the resonator element 5 may be of a mesa type in which a resonance area interposed between the excitation electrodes 521 and 522 protrudes from the surrounding area of the resonance area. Conversely, the resonator element 5 may be of an inverted mesa type in which the resonance area recessed from the surrounding area of the resonance area. In addition, a bevel process of grinding the surrounding area of the resonator substrate 51, or a convex process of forming the upper surface and the lower surface of the resonator substrate 51 into convex surfaces may be performed.

The resonator element 5 that resonates in the thickness shear resonance mode is not for limitation purposes. For example, the resonator element 5 may be a tuning fork type resonator element of which two vibrating arms are subjected to tuning fork resonance in an in-plane direction. That is, the resonator substrate 51 is not limited to the AT cut quartz crystal substrate and may be a quartz crystal substrate other than the AT cut quartz crystal substrate such as an X cut quartz crystal substrate, a Y cut quartz crystal substrate, a Z cut quartz crystal substrate, a BT cut quartz crystal substrate, an SC cut quartz crystal substrate, or an ST cut quartz crystal substrate. In the present embodiment, the resonator substrate is formed of quartz crystal. However, the present embodiment is not for limitation purposes. For example, the resonator substrate 51 may be formed of a piezoelectric single crystal such as lithium niobate, lithium tantalate, lithium tetraborate, langasite, potassium niobate, or gallium phosphate, or may be formed of other piezoelectric single crystals. Furthermore, the resonator element 5 is not limited to the piezoelectric drive type resonator element and may be an electrostatic drive type resonator element that uses electrostatic force.

As illustrated in FIG. 2 and FIG. 3, the resonator element 5 is fixed on the upper surface of the base 4 by conductive bonding members B1 and B2. The conductive bonding member B1 electrically couples the internal terminal 441 of the base 4 to the terminal 523 of the resonator element 5. The conductive bonding member B2 electrically couples the internal terminal 451 of the base 4 to the terminal 524 of the resonator element 5.

The conductive bonding members B1 and B2 are not particularly limited as long as the conductive bonding members B1 and B2 have both conductivity and bondability. For example, various metal bumps such as a gold bump, a silver bump, a copper bump, and a solder bump, and conductive adhesives obtained by dispersing a conductive filler such as a silver filler into various polyimide-based, epoxy-based, silicone-based, and acrylic-based adhesives can be used. When the former metal bumps are used as the conductive bonding members B1 and B2, the occurrence of gas from the conductive bonding members B1 and B2 can be reduced, and an environmental change in the accommodation space S, particularly, an increase in pressure, can be effectively reduced. Meanwhile, when the latter conductive adhesives are used as the conductive bonding members B1 and B2, the conductive bonding members B1 and B2 are softer than the metal bumps, and stress is unlikely to occur in the resonator element 5.

The resonator device 1 is described thus far. As described above, the resonator device 1 includes the base substrate 41 that includes the upper surface 412 which is the principal surface, the side surface 413, and the inclined surface 414 which couples the upper surface 412 to the side surface 413 and that is inclined with respect to the upper surface 412 and the side surface 413, the resonator element 5 that is arranged on the upper surface 412 side of the base substrate 41, and the lid 3 that is a cover bonded to the upper surface 412 of the base substrate 41 such that the resonator element 5 is accommodated between the lid 3 and the base substrate 41. The bonding area Q between the base substrate 41 and the lid 3 is positioned inside the outer edge 412a of the upper surface 412. By disposing the inclined surface 414 in the base substrate 41, the corner C between the upper surface 412 and the side surface 413 is cut. Thus, concentration of stress on the corner C is reduced, and the occurrence of a chip or a crack starting from the corner C can be effectively reduced. Furthermore, since the bonding area Q between the base substrate 41 and the lid 3 is positioned inside the outer edge 412a of the upper surface 412, the bonding area Q is unlikely to directly receive external force. Accordingly, excessive stress is unlikely to be applied to the bonding area Q, and a decrease in strength or breakage of the bonding area Q can be effectively reduced. Thus, the resonator device 1 having excellent mechanical strength is obtained.

As described above, the base substrate 41 is the single crystal silicon substrate. The upper surface 412 is the (100) crystal surface. Accordingly, the base substrate 41 can be inexpensively formed with excellent processing accuracy. In addition, the inclined surface 414 can be easily formed by wet etching.

As described above, the side surface 413 is a fractured surface. Accordingly, the side surface 413 is obtained as a smoother surface. Thus, parts on which stress is concentrated are reduced, and a chip or a crack is more unlikely to occur in the base substrate 41.

As described above, the base substrate 41 and the lid 3 are directly bonded. Accordingly, the base substrate 41 and the lid 3 can be more firmly bonded. In addition, bonding can be performed at room temperature. Thus, the resonator device 1 in which residual stress is sufficiently reduced can be manufactured.

As described above, the side surface 38 of the lid 3 includes at least one corner 39, and the corner 39 is rounded. Accordingly, concentration of stress on the corner 39 is reduced, and the occurrence of a chip of the lid 3 or a crack in the lid 3 can be effectively reduced. Thus, the resonator device 1 having excellent mechanical strength is obtained.

Next, a manufacturing method for the resonator device 1 will be described. As illustrated in FIG. 8, the manufacturing method for the resonator device 1 includes a resonator element attaching step of preparing a base wafer 400 including a plurality of integrated bases 4 and attaching the resonator element 5 to each base 4, a bonding step of bonding a lid wafer 300 including a plurality of integrated lids 3 to the base wafer 400 and forming a device wafer 100 including a plurality of integrated resonator devices 1, and a dicing step of dicing the plurality of resonator devices 1 from the device wafer 100. Hereinafter, the manufacturing method will be described based on FIG. 9 to FIG. 19. FIG. 9 to FIG. 19 are sectional views corresponding to FIG. 2.

### Resonator Element Attaching Step

First, as illustrated in FIG. 9, a silicon wafer SW1 that is a base material of the base substrate 41 is prepared. The silicon wafer SW1 is a single crystal silicon wafer of which the upper surface is the (100) crystal surface. In the silicon wafer SW1, a plurality of dicing areas R each of which forms one base substrate 41 by a dicing step described later are arranged in a matrix. Next, in each dicing area R, two bottomed recesses SW11 are formed from the upper surface side of the silicon wafer SW1. For example, the recess SW11 can be formed by dry etching represented by the Bosch process. Next, as illustrated in FIG. 10, the silicon wafer SW1 is ground and polished from the lower surface side of the silicon wafer SW1. The silicon wafer SW1 is thinned until the recess SW11 passes through the silicon wafer SW1. Accordingly, the through holes 415 and 416 are formed in each dicing area R.

Next, as illustrated in FIG. 11, the insulating film 42 that is formed with a silicon oxide film is formed on the surface of the silicon wafer SW1. Furthermore, the electrode 43 is formed on the insulating film 42 in each dicing area R. For example, the insulating film 42 can be formed by thermal oxidation or a plasma CVD method using TEOS. The electrode 43 can be formed by depositing a metal film on the insulating film 42 by vapor deposition or sputtering and patterning the metal film by etching. The insulating film 42 on the upper surface of the silicon wafer SW1 may be formed before the present step.

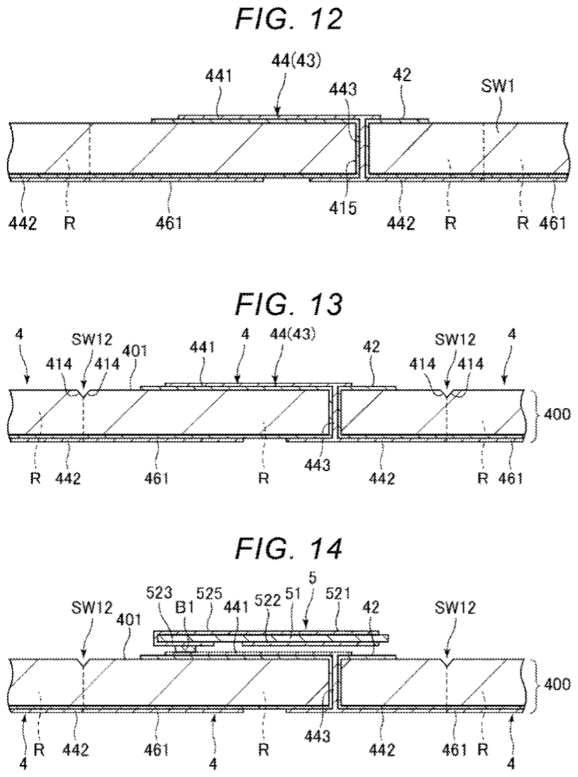

Next, as illustrated in FIG. 12, a part of the insulating film 42 on the upper surface of the silicon wafer SW1 is removed, and the upper surface is exposed from the insulating film 42 in a part that is the bonding area Q with respect to the lid wafer 300. Next, as illustrated in FIG. 13, a groove SW12 is formed on a boundary between adjacent dicing areas R from the upper surface side. The groove SW12 has a V-shaped transverse section and has a tapered shape in which the width of the groove SW12 decreases in the depth direction. The tip end of the groove SW12 is sufficiently pointed. For example, the groove SW12 can be formed by wet etching. According to the wet etching, the (111) crystal surface, the (101) crystal surface, and the like that are inclined with respect to the upper surface are exposed. Thus, the V-shaped groove SW12 can be easily formed using the crystal surfaces. The groove SW12 functions as causing fracture in dicing described later and constitutes the inclined surface 414. Through the steps described thus far, a base wafer 400 in which a plurality of bases 4 are integrated is obtained. Next, as illustrated in FIG. 14, the resonator element 5 is attached to the upper surface side of each base 4.

### Bonding Step

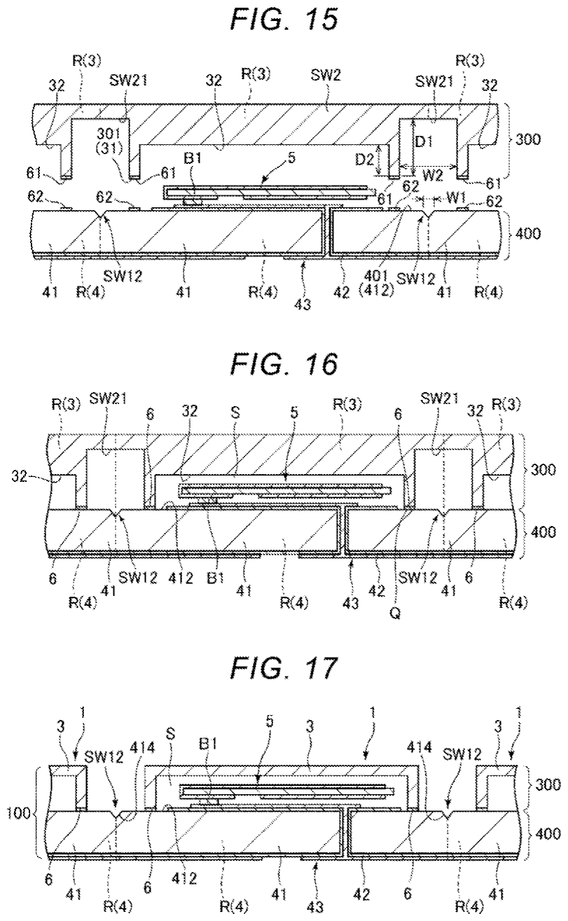

First, as illustrated in FIG. 15, a silicon wafer SW2 that is a base material of the lid 3 is prepared. The silicon wafer SW2 is a single crystal silicon wafer of which the principal surface is the (100) crystal surface. In the silicon wafer SW2, a plurality of dicing areas R each of which forms one lid 3 by dicing described later are arranged in a matrix. Next, the bottomed recess 32 is formed in each dicing area R from the lower surface side of the silicon wafer SW2, and a recess SW21 is formed along a boundary between adjacent dicing areas R. For example, the recesses 32 and SW21 can be formed by dry etching represented by the Bosch process. A depth D1 of the recess SW21 is greater than a depth D2 of the recess 32. An opening width W2 of the recess SW21 is greater than an opening width W1 of the groove SW12. Through the steps described thus far, a lid wafer 300 in which a plurality of lids 3 are integrated is obtained.

Next, the metal film 62 is formed on the upper surface 412 of each base substrate 41, and the metal film 61 is formed on the lower surface 31 of each lid 3. Next, for example, the metal films 61 and 62 are activated by blowing Ar gas to the metal films 61 and 62. As illustrated in FIG. 16, the base wafer 400 and the lid wafer 300 are directly bonded by diffusion-bonding the metal films 61 and 62. As described above, since the opening width W2 of the recess SW21 is greater than the opening width W1 of the groove SW12, the bonding area Q between the base substrate 41 and the lid 3 is positioned inside the outer edge 412a of the upper surface 412 in each dicing area R.

Next, as illustrated in FIG. 17, the lid wafer 300 is ground and polished from the upper surface of the lid wafer 300, and the lid wafer 300 is thinned until the recess SW21 passes through the lid wafer 300. Accordingly, the lid 3 in each dicing area R is diced. Through the steps described thus far, a device wafer 100 in which a plurality of resonator devices 1 are integrated is obtained.

### Dicing Step

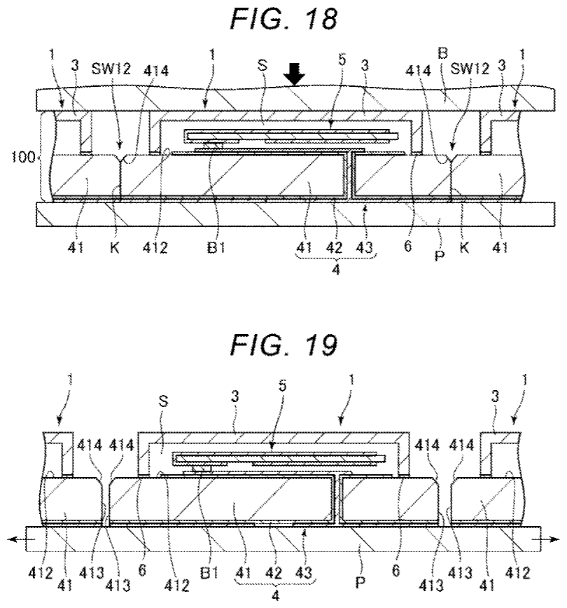

As illustrated in FIG. 18, the device wafer 100 is mounted on a sheet P having flexibility and is pressed with a pressing member B such as a roller from above. Accordingly, a crack K is developed from the apex of the V-shaped groove SW12, and the plurality of resonator devices 1 are diced as illustrated in FIG. 19. In the manufactured resonator device 1, the side surface 413 of the base substrate 41 is configured as a fractured surface, and the inclined surface 414 is configured as an etched surface. A dicing method is not particularly limited. FIG. 19 illustrates a state where adjacent resonator devices 1 are separated from each other by extending the sheet P.

The manufacturing method for the resonator device 1 is described thus far. The manufacturing method for the resonator device 1 includes a step of preparing the base wafer 400 that includes the plurality of dicing areas R and in which the groove SW12 is formed along the boundary between the adjacent dicing areas Ron the upper surface 401 side as a first surface which is one principal surface, and arranging the resonator element 5 on the upper surface 401 side in each dicing area R, a step of preparing the lid wafer 300 that includes the plurality of dicing areas R and in which the recess 32 which is a first recess accommodating the resonator element 5 and the recess SW21 which is a second recess along the boundary between the adjacent dicing areas R and which has the depth D1 greater than the depth D2 of the recess 32 and the opening width W2 greater than the opening width W1 of the groove SW12 are formed on the lower surface 301 side as a second surface which is the principal surface on the base wafer 400 side, and obtaining the device wafer 100 that is a stack of the base wafer 400 and the lid wafer 300 by bonding the upper surface 401 to the lower surface 301, and a step of dicing each dicing area R by fracturing the base wafer 400 from the tip end of the groove SW12 by applying stress to the device wafer 100.

According to the manufacturing method, a plurality of resonator devices 1 having high mechanical strength can be manufactured at the same time. Particularly, in the dicing step, the apex of the groove SW12 as a starting point of fracture is sufficiently separated from the bonding area Q. Thus, excessive stress is unlikely to be applied to the bonding area Q, and a decrease in strength of the bonding area Q or breakage of the bonding area Q at the time of manufacturing can be reduced.

In the present embodiment, in the step of preparing the base wafer 400, the groove SW12 forms a groove that is tapered in sectional view. By using this configuration, the base wafer 400 can be easily fractured from the tip end of the groove SW12 in the dicing step.

### Second Embodiment

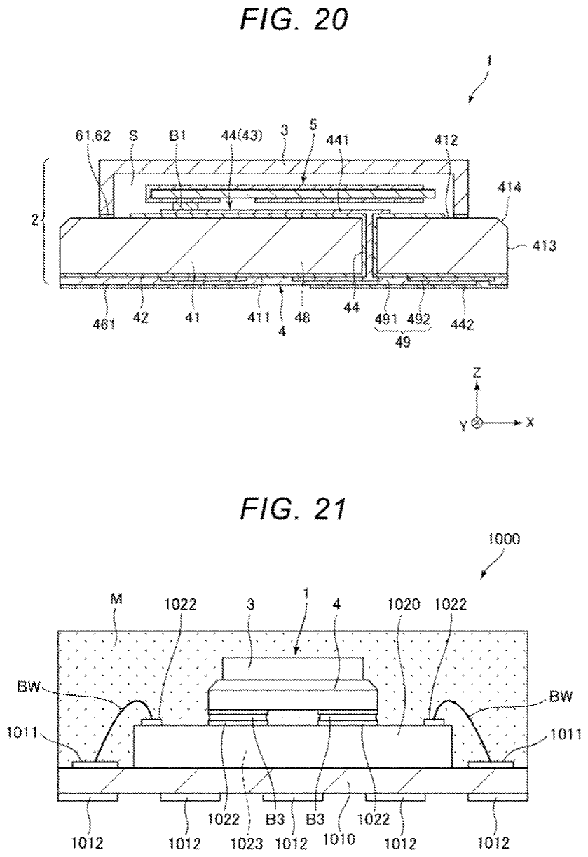

FIG. 20 is a sectional view illustrating a resonator device according to a second embodiment.

The resonator device 1 according to the present embodiment is the same as the resonator device 1 of the first embodiment except that an oscillation circuit 48 is formed in the base 4. In the following description, differences between the resonator device 1 of the second embodiment and the resonator device 1 of the first embodiment will be mainly described, and the same matters will not be described. In FIG. 20, the same configurations as the above embodiments are designated by the same reference signs.

In the resonator device 1 of the present embodiment, as illustrated in FIG. 20, the oscillation circuit 48 electrically coupled to the resonator element 5 is formed in the base 4. In the present embodiment, the lower surface 411 of the base substrate 41 is set as an active surface. In addition, a stack 49 in which an insulating layer 491 and an interconnect layer 492 are stacked is disposed on the lower surface 411 of the base substrate 41. A plurality of circuit elements (not illustrated) formed on the lower surface 411 are electrically coupled through the interconnect layer 492 and constitute the oscillation circuit 48. By forming the oscillation circuit 48 in the base 4, the space of the base 4 can be effectively used.

According to the second embodiment, the same effect as the first embodiment can be exhibited. In the present embodiment, the lower surface 411 of the base substrate 41 is set as the active surface. However, the present embodiment is not for limitation purposes. The upper surface 412 of the base substrate 41 may be set as the active surface. By setting the upper surface 412 of the base substrate 41 as the active surface, the resonator device and the oscillation circuit 48 can be electrically coupled at a low impedance. Thus, oscillation of the oscillation circuit 48 can be stabilized.

### Third Embodiment

FIG. 21 is a sectional view illustrating a resonator module according to a third embodiment.

A resonator module 1000 illustrated in FIG. 21 includes a support substrate 1010, a circuit substrate 1020 mounted on the support substrate 1010, the resonator device 1 mounted on the circuit substrate 1020, and a mold material M molding the circuit substrate 1020 and the resonator device 1.

For example, the support substrate 1010 is an interposer substrate. A plurality of coupling terminals 1011 are arranged on the upper surface of the support substrate 1010. A plurality of mount terminals 1012 are arranged on the lower surface of the support substrate 1010. An internal interconnect, not illustrated, is arranged in the support substrate 1010. Each coupling terminal 1011 is electrically coupled to the corresponding mount terminal 1012 through the internal interconnect. The support substrate 1010 is not particularly limited. For example, a silicon substrate, a ceramic substrate, a resin substrate, a glass substrate, or a glass epoxy substrate can be used.

The circuit substrate 1020 is bonded to the upper surface of the support substrate 1010 through a die attaching material. In the circuit substrate 1020, an oscillation circuit 1023 that generates the frequency of a reference signal such as a clock signal by oscillating the resonator element 5 of the resonator device 1 is formed. A plurality of terminals 1022 electrically coupled to the oscillation circuit are arranged on the upper surface of the oscillation circuit 1023. A part of the terminals 1022 is electrically coupled to the coupling terminals 1011 through bonding wires BW. A part of the terminals 1022 are electrically coupled to the resonator device 1 through a conductive bonding member B3 such as solder.

The mold material M molds the circuit substrate 1020 and the resonator device 1 and protects the circuit substrate 1020 and the resonator device 1 from moisture, dust, shock, and the like. The mold material M is not particularly limited. For example, a thermosetting type epoxy resin can be used, and the molding can be performed using a transfer molding method.

The resonator module 1000 includes the resonator device 1. Thus, the effect of the resonator device 1 can be accomplished, and excellent reliability can be exhibited. Particularly, as described above, in the resonator device 1, the corners 39 of the side surface 38 of the lid 3 are rounded. Thus, the mold material M easily flows around the lid 3 during the molding. Thus, voids are unlikely to occur during the molding, and the resonator device 1 and the circuit substrate 1020 can be more securely protected from moisture and the like.

### Fourth Embodiment

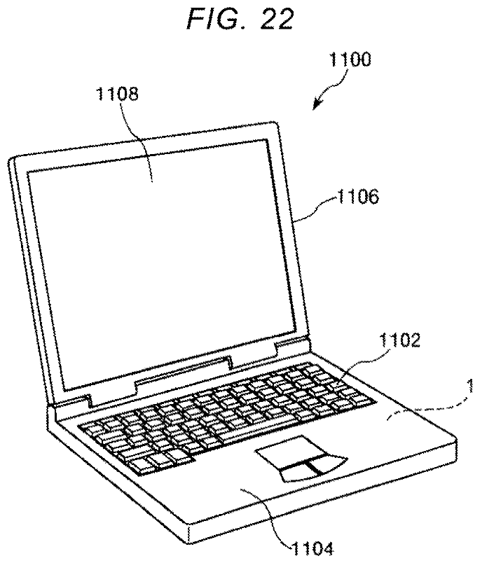

FIG. 22 is a perspective view illustrating an electronic apparatus according to a fourth embodiment.

The electronic apparatus including the resonator device according to the present disclosure is applied to a laptop type personal computer 1100 illustrated in FIG. 22. In FIG. 22, the personal computer 1100 is configured with a main body 1104 including a keyboard 1102, and a display unit 1106 including a display 1108. The display unit 1106 is pivotably supported with respect to the main body 1104 through a hinge structure. For example, the resonator device 1 used as an oscillator is incorporated in the personal computer 1100.

The personal computer 1100 as the electronic apparatus includes the resonator device 1. Thus, the effect of the resonator device 1 can be accomplished, and high reliability can be exhibited.

### Fifth Embodiment

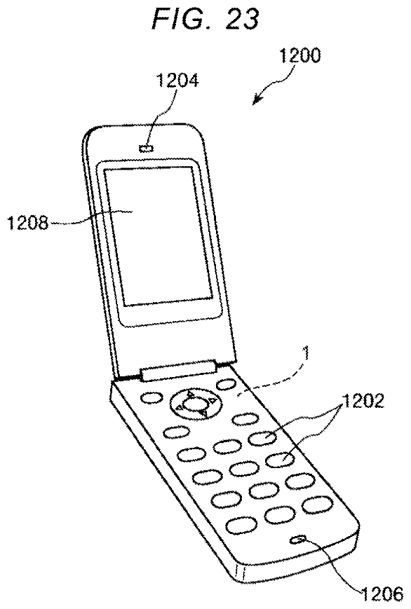

FIG. 23 is a perspective view illustrating an electronic apparatus according to a fifth embodiment.

The electronic apparatus including the resonator device according to the present disclosure is applied to a mobile phone 1200 illustrated in FIG. 23. The mobile phone 1200 includes an antenna, a plurality of operation buttons 1202, a receiver 1204, and a transmitter 1206. A display 1208 is arranged between the operation buttons 1202 and the receiver 1204. For example, the resonator device 1 used as an oscillator is incorporated in the mobile phone 1200.

The mobile phone 1200 as the electronic apparatus includes the resonator device 1. Thus, the effect of the resonator device 1 can be accomplished, and high reliability can be exhibited.

### Sixth Embodiment

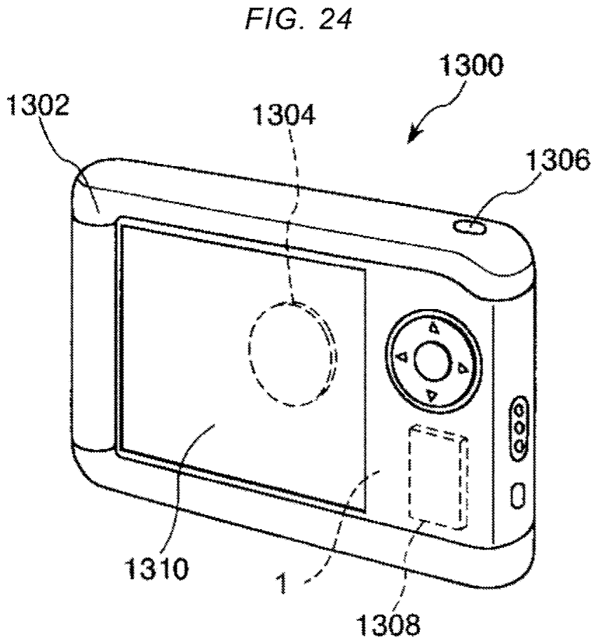

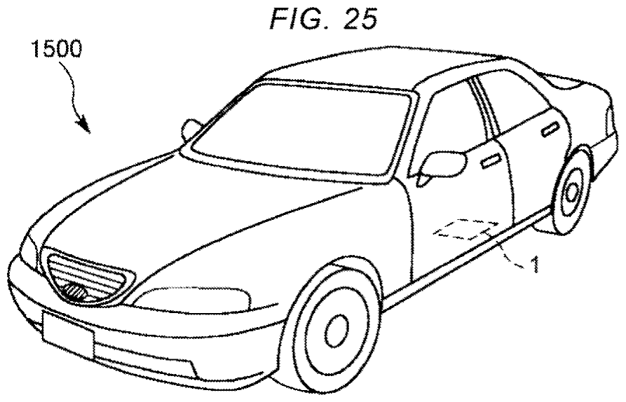

FIG. 24 is a perspective view illustrating an electronic apparatus according to a sixth embodiment.

The electronic apparatus including the resonator device according to the present disclosure is applied to a digital still camera 1300 illustrated in FIG. 24. A display 1310 is disposed on the rear surface of a body 1302 and is configured to perform displaying based on an imaging signal of a CCD. The display 1310 functions as a finder that displays a subject as an electronic image. A light receptor 1304 that includes an optical lens, a CCD, and the like is disposed on the front surface side (in FIG. 24, the rear surface side) of the body 1302. When a camera operator checks the subject image displayed on the display 1310 and presses a shutter button 1306, the imaging signal of the CCD at that time point is transferred to and stored in a memory 1308. For example, the resonator device 1 used as an oscillator is incorporated in the digital still camera 1300.

The digital still camera 1300 as the electronic apparatus includes the resonator device 1. Thus, the effect of the resonator device 1 can be accomplished, and high reliability can be exhibited.

In addition to the personal computer, the mobile phone, and the digital still camera, for example, the electronic apparatus according to the present disclosure can be applied to a smartphone, a tablet terminal, a timepiece (including a smart watch), an ink jet type ejecting apparatus (for example, an ink jet printer), a laptop type personal computer, a television, a wearable terminal such as a head-mounted display (HMD), a video camera, a video tape recorder, a car navigation apparatus, a pager, an electronic organizer (including an electronic organizer having a communication function), an electronic dictionary, an electronic calculator, an electronic game apparatus, a word processor, a workstation, a videophone, a security television monitor, an electronic binocular, a POS terminal, a medical apparatus (for example, an electronic thermometer, a blood pressure meter, a blood glucose meter, an electrocardiograph, an ultrasound diagnosis apparatus, and an electronic endoscope), a fishfinder, various measuring apparatuses, a mobile terminal base station apparatus, meters (for examples, meters of a vehicle, an aircraft, and a ship), a flight simulator, a network server, and the like.

### Seventh Embodiment

FIG. 25 is a perspective view illustrating a vehicle according to a seventh embodiment.

An automobile 1500 illustrated in FIG. 25 is an automobile to which the vehicle including the resonator device according to the present disclosure is applied. For example, the resonator device 1 used as an oscillator is incorporated in the automobile 1500. The resonator device 1 can be widely applied to keyless entry, an immobilizer, a car navigation system, a car air conditioner, an antilock brake system (ABS), an airbag, a tire pressure monitoring system (TPMS), engine control, a battery monitor of a hybrid automobile or an electric automobile, and an electronic control unit (ECU) such as a vehicle attitude control system.

The automobile 1500 as the vehicle includes the resonator device 1. Thus, the effect of the resonator device 1 can be accomplished, and high reliability can be exhibited.

The vehicle is not limited to the automobile 1500 and can be applied to an airplane, a ship, an automatic guided vehicle (AGV), a biped robot, an unmanned airplane such as a drone, and the like.

While the resonator device, the manufacturing method for the resonator device, the resonator module, the electronic apparatus, and the vehicle of the present application example are described thus far based on the illustrated embodiments, the present disclosure is not limited to the embodiments. The configuration of each unit can be replaced with any configuration having the same function. Any other constituents may be added to the present disclosure. The present disclosure may be a combination of any two or more configurations in each of the embodiments.

What is claimed is:

1. A resonator device comprising:
a base substrate including a principal surface, a side surface, and an inclined surface that couples the principal surface to the side surface and that is inclined with respect to the principal surface and the side surface;
a resonator element arranged on the principal surface of the base substrate; and
a lid that is bonded to the principal surface of the base substrate and that accommodates the resonator element between the lid and the base substrate, wherein
a bonding area in which the base substrate and the lid are bonded is positioned inside an outer edge of the principal surface.

2. The resonator device according to claim 1, wherein
the base substrate is a single crystal silicon substrate and
the principal surface is a (100) crystal surface.

3. The resonator device according to claim 1, wherein
the side surface is a fractured surface.

4. The resonator device according to claim 1, wherein
the base substrate and the lid are directly bonded.

5. The resonator device according to claim 1, wherein
the lid includes a side surface having at least one corner, and the corner is rounded.

6. A resonator module comprising:
the resonator device according to claim 1; and
an oscillation circuit oscillating the resonator element.

7. An electronic apparatus comprising:
the resonator device according to claim 1.

8. A vehicle comprising:
the resonator device according to claim 1.
